(19) United States
(12) Patent Application Publication
(10) Pub. No.: US 2026/0052931 A1
(43) Pub. Date: Feb. 19, 2026

(54) SEMICONDUCTOR FABRICATION STATION RESCUE SYSTEM

(71) Applicant: Taiwan Semiconductor Manufacturing Company Limited, Hsin-Chu (TW)

(72) Inventors: Bing-Yue SHEN, Taichung City (TW); Kai-Hsiang LO, Hsinchu County (TW); Yu-Wen FANG, Hsinchu County (TW); Shing Long LEE, Hsinchu City (TW)

(21) Appl. No.: 18/802,168

(22) Filed: Aug. 13, 2024

(51) Int. Cl. H01L 21/67; H01L 21/02; H01L 21/3213

(52) U.S. Cl. CPC H01L 21/67057; H01L 21/02068; H01L 21/32134; H01L 21/67086; H01L 21/67242

(57) ABSTRACT

A system is provided. The system includes a semiconductor fabrication station and a rescue system. The semiconductor fabrication station includes a tank to hold a liquid. The semiconductor fabrication station is configured to perform a semiconductor fabrication process on a semiconductor wafer disposed in the tank. The rescue system is configured to monitor a signal line indicative of a state of the semiconductor fabrication station. The rescue system is configured to open a drain valve of the tank to drain the liquid from the tank in response to the signal line indicating a potential fabrication station error.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a diagram of a system comprising a rescue system and a semiconductor fabrication station, in accordance with some embodiments.

FIG. 1B illustrates a diagram of a system comprising a rescue system and a semiconductor fabrication station, in accordance with some embodiments.

FIG. 2A illustrates a diagram of a rescue scenario associated with using a rescue system to perform a set of rescue actions, in accordance with some embodiments.

FIG. 2B illustrates a diagram of an overflow scenario associated with a semiconductor fabrication station, in accordance with some embodiments.

FIG. 3A illustrates a map of a semiconductor fabrication station, in accordance with some embodiments.

FIG. 3B illustrates a diagram of a system comprising a rescue system and a semiconductor fabrication station, in accordance with some embodiments.

FIG. 4 is a flow diagram illustrating a method, in accordance with some embodiments.

FIG. 5 is a flow diagram illustrating a method, in accordance with some embodiments.

FIG. 6 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A semiconductor fabrication station has a tank to hold a liquid. The semiconductor fabrication station is configured to perform a semiconductor fabrication process on a semiconductor wafer disposed in the tank. In some embodiments, the semiconductor fabrication station has a showerhead. A rescue system is configured to monitor a signal line indicative of a state of the semiconductor fabrication station. In response to the signal line indicating a potential fabrication station error rescue system, the rescue system triggers one or more rescue actions including at least one of opening a drain valve of the tank to drain a liquid from the tank or emitting a gas from the showerhead to reduce a moisture level of the semiconductor wafer. In some embodiments, performing the one or more rescue actions mitigates and/or prevents damage, such as water damage, to the semiconductor wafer that would otherwise occur if the one or more rescue actions were not performed. In some embodiments, using the techniques provided herein provides for saving the semiconductor wafer from being scrapped, thereby providing for at least one of improved production efficiency and/or throughput of the semiconductor fabrication station, reduced waste, etc.

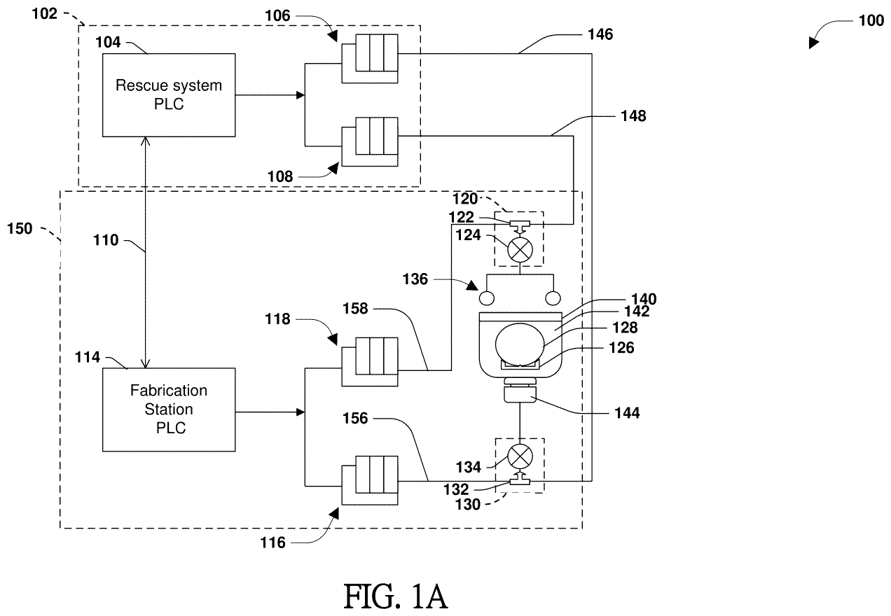

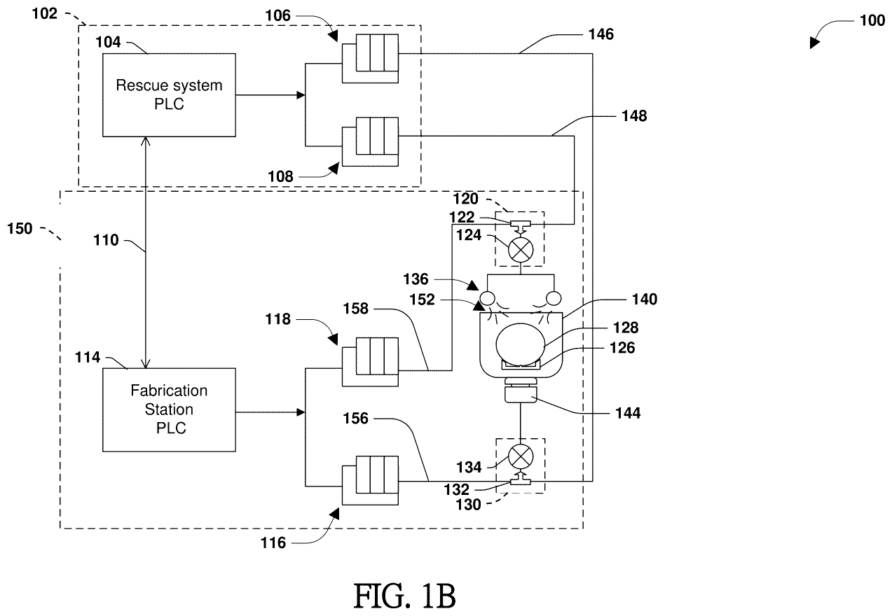

FIG. 1A illustrates a system 100 comprising a rescue system 102 and a semiconductor fabrication station 150, according to some embodiments. In some embodiments, the rescue system 102 comprises at least one of a rescue system controller 104, a first valve control unit 106, or a second valve control unit 108. The rescue system controller 104 comprises a first programmable logic controller (PLC). In some embodiments, the semiconductor fabrication station 150 comprises a semiconductor fabrication station controller 114. The semiconductor fabrication station controller 114 comprises a second PLC. Other types of controllers (other than and/or in addition to PLC-type controllers) of the rescue system controller 104 and the semiconductor fabrication station controller 114 are within the scope of the present disclosure.

In some embodiments, the semiconductor fabrication station 150 is configured to perform a first semiconductor fabrication process on a first semiconductor wafer 128. In some embodiments, the first semiconductor fabrication process comprises at least one of an etching process, a PVD process, a plating process, an ion implantation process, a lithography process, a CMP process, a CVD process, a thermal process, a cleaning process, or other process. In some embodiments, the semiconductor fabrication station 150 comprises at least one of (i) etching equipment, such as at least one of wet etching equipment, plasma etching equipment, dry etching equipment, reactive-ion etching (RIE) equipment, atomic layer etching (ALE) equipment, buffered oxide etching equipment, or ion beam milling equipment, (ii) chemical vapor deposition (CVD) equipment, (iii) physical vapor deposition (PVD) equipment, (iv) ion implantation equipment, (v) lithography equipment, (vi) chemical mechanical planarization (CMP) equipment, (vii) plating equipment, (viii) cleaning equipment, (ix) a furnace, such as a semiconductor furnace tool, or (x) other equipment. In some embodiments, the semiconductor fabrication station 150 comprises a wafer bench (e.g., a wet bench) for processing (e.g., cleaning and/or etching) the first semiconductor wafer 128.

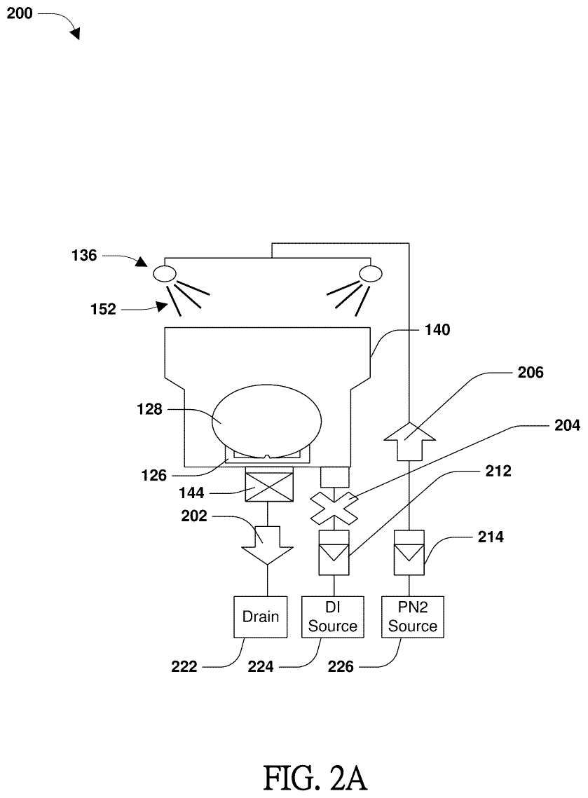

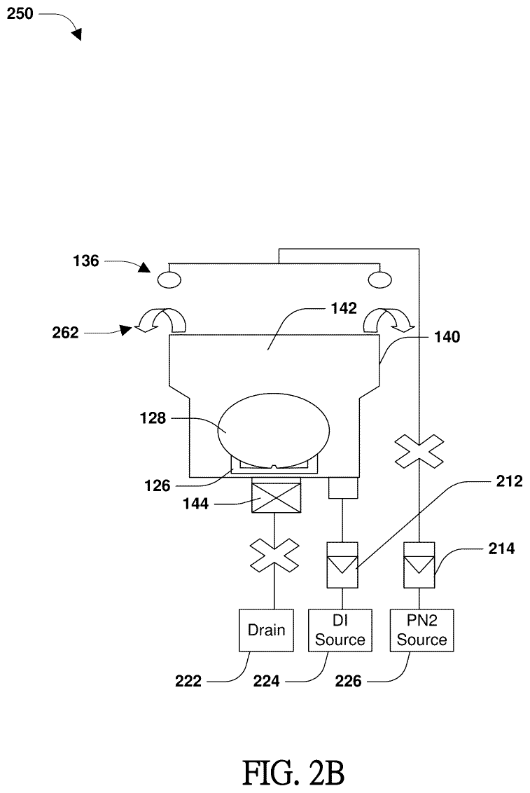

In some embodiments, the semiconductor fabrication station 150 comprises a tank 140 in which the first semiconductor wafer 128 is disposed. In some embodiments, the tank 140 is configured to hold a liquid 142. In some embodiments, the liquid 142 is conducted from a liquid source 224 (shown in FIG. 2A) to the tank 140. In some embodiments, at least one of the liquid 142 or the first semiconductor wafer 128 is disposed in a chamber defined by the tank 140. In some embodiments, the liquid 142 comprises at least one of water, de-ionized water, one or more cleaning chemicals, one or more etching chemicals, or one or more other suitable substances. In some embodiments, the first semiconductor wafer 128 is in contact with and/or submerged in the liquid 142. In some embodiments, the semiconductor fabrication station 150 comprises a wafer holder 126 configured to support the first semiconductor wafer 128 in the tank 140. In some embodiments, the semiconductor fabrication station 150 comprises a set of drain valves 130 (e.g., a set of one or more drain valves) connected to the tank 140. In some embodiments, each valve of one, some or all valves of the set of drain valves 130 comprises or is controlled using a magnetic valve or other type of valve. In some embodiments, the magnetic valve comprises a solenoid valve. In some embodiments, the set of drain valves 130 comprise at least one of a shuttle valve 132, a valve 134, or one or more other suitable valves.

In some embodiments, the semiconductor fabrication station 150 comprises a showerhead 136 for emitting a gas. The gas comprises at least one of nitrogen (e.g., at least one of dinitrogen (N₂), pure dinitrogen (PN2), etc.) or other suitable gas. In some embodiments, the semiconductor fabrication station 150 comprises a set of showerhead valves 120 (e.g., a set of one or more showerhead valves) connected to the showerhead 136. In some embodiments, the set of showerhead valves 120 comprise at least one of a shuttle valve 122, a valve 124, or one or more other suitable valves. In some embodiments, the showerhead 136 overlies at least one of the first semiconductor wafer 128 or the wafer holder 126.

In some embodiments, the rescue system 102 comprises at least one of a first valve control unit 106 (e.g., an electronic valve unit) configured to control the set of drain valves 130 or a second valve control unit 108 (e.g., an electronic valve unit) configured to control the set of showerhead valves 120. In some embodiments, the rescue system controller 104 is at least one of connected to the first valve control unit 106 via a wired or wireless connection or connected to the second valve control unit 108 via a wired or wireless connection. In some embodiments, the first valve control unit 106 is connected to (and/or controls) the set of drain valves 130 via a first set of tubes 146 (e.g., a first set of one or more tubes, such as at least one of one or more plastic tubes, one or more flexible tubes, one or more pipes, etc.) configured to conduct fluid comprising at least one of liquid or gas between the first valve control unit 106 and the set of drain valves 130. In some embodiments, the second valve control unit 108 is connected to (and/or controls) the set of showerhead valves 120 via a second set of tubes 148 (e.g., a second set of one or more tubes, such as at least one of one or more plastic tubes, one or more flexible tubes, one or more pipes, etc.) configured to conduct fluid comprising at least one of liquid or gas between the second valve control unit 108 and the set of showerhead valves 120.

In some embodiments, the semiconductor fabrication station 150 comprises at least one of a third valve control unit 116 (e.g., an electronic valve unit) configured to control the set of drain valves 130 or a fourth valve control unit 118 (e.g., an electronic valve unit) configured to control the set of showerhead valves 120. In some embodiments, the semiconductor fabrication station controller 114 is connected to at least one of the third valve control unit 116 or the fourth valve control unit 118. In some embodiments, the third valve control unit 116 is connected to (and/or controls) the set of drain valves 130 via a third set of tubes 156 (e.g., a third set of one or more tubes, such as at least one of one or more plastic tubes, one or more flexible tubes, one or more pipes, etc.) configured to conduct fluid comprising at least one of liquid or gas between the third valve control unit 116 and the set of drain valves 130. In some embodiments, the fourth valve control unit 118 is connected to (and/or controls) the set of showerhead valves 120 via a fourth set of tubes 158 (e.g., a fourth set of one or more tubes, such as at least one of one or more plastic tubes, one or more flexible tubes, one or more pipes, etc.) configured to conduct fluid comprising at least one of liquid or gas between the fourth valve control unit 118 and the set of showerhead valves 120.

In some embodiments, the semiconductor fabrication station controller 114 communicates with the third valve control unit 116 to control the set of drain valves 130. In some embodiments, the semiconductor fabrication station controller 114 communicates with the third valve control unit 116 and/or controls the set of drain valves 130 based upon one or more parameters of the first semiconductor fabrication process. In some embodiments, the semiconductor fabrication station controller 114 communicates with the third valve control unit 116 and/or controls the set of drain valves 130 to control a state of the set of drain valves 130. In some embodiments, the semiconductor fabrication station controller 114 communicates with the third valve control unit 116 and/or controls the set of drain valves 130 to switch the state of the set of drain valves 130 between a first open drain state and a first closed drain state. In some embodiments, when the set of drain valves 130 is in the first open drain state, one or more valves of the set of drain valves 130 are opened to establish a first flow path, through the one or more valves, through which the liquid 142 is allowed to be drained from the tank 140 to a drain location 222 (shown in FIG. 2A) outside of the tank 140. In some embodiments, the drain location 222 comprises a reservoir for storing used liquid. In some embodiments, when the set of drain valves 130 is in the first closed drain state, one or more valves of the set of drain valves 130 are closed to block and/or mitigate the liquid 142 exiting the tank 140.

In some embodiments, the semiconductor fabrication station controller 114 communicates with the fourth valve control unit 118 to control the set of showerhead valves 120. In some embodiments, the semiconductor fabrication station controller 114 communicates with the fourth valve control unit 118 and/or controls the set of showerhead valves 120 based upon one or more parameters of the first semiconductor fabrication process. In some embodiments, the semiconductor fabrication station controller 114 communicates with the fourth valve control unit 118 and/or controls the set of showerhead valves 120 to control a state of the set of showerhead valves 120. In some embodiments, the semiconductor fabrication station controller 114 communicates with the fourth valve control unit 118 and/or controls the set of showerhead valves 120 to switch the state of the set of showerhead valves 120 between a first open showerhead state and a first closed showerhead state. In some embodiments, when the set of showerhead valves 120 is in the first open showerhead state, one or more valves of the set of showerhead valves 120 are opened to establish a second flow path, through the one or more valves, through which a gas is allowed to flow from a gas source 226 (shown in FIG. 2A) to the showerhead 136 to be emitted through the showerhead 136. In some embodiments, the gas source 226 comprises a reservoir for storing the gas. In some embodiments, when the set of showerhead valves 120 is in the first closed showerhead state, one or more valves of the set of showerhead valves 120 are closed to block and/or mitigate flow of the gas to and/or through the showerhead 136. The gas comprises at least one of nitrogen (e.g., at least one of N₂, PN2, etc.) or other suitable gas.

In some embodiments, the rescue system controller 104 monitors a signal line 110 indicative of a station state of the semiconductor fabrication station 150. In some embodiments, the semiconductor fabrication station controller 114 comprises a signal generation module that generates and/or transmits a signal, over the signal line 110, that is indicative of the station state. In some embodiments, the station state is indicative of whether the semiconductor fabrication station 150 is associated with a potential fabrication station error. In some embodiments, the signal line 110 (and/or the signal on the signal line 110) is indicative of a first value (e.g., a first voltage, a first digital value, a first binary value, etc.) to indicate that the semiconductor fabrication station 150 is at least one of (i) not associated with a potential fabrication station error or (ii) associated with normal operation. In some embodiments, the signal line 110 is indicative of a second value (e.g., a second voltage, a second digital value, a second binary value, etc.) to indicate that the semiconductor fabrication station 150 is associated with a potential fabrication station error (e.g., abnormal operation).

In some embodiments, the signal generation module generates the signal on the signal line 110 using an input/output protocol (e.g., a PLC input/output protocol) of the rescue system controller 104 (e.g., the first PLC). In some embodiments, the rescue system controller 104 (e.g., the first PLC) comprises at least one of a transistor type PLC control system, a relay type PLC control system, or other type of PLC control system. In some embodiments, the signal on the signal line 110 is generated using a first program enabled on the transistor type PLC control system and a second program enabled on the relay type PLC control system. Embodiments are contemplated in which the signal on the signal line 110 is generated using merely one of the first program enabled on the transistor type PLC control system or the second program enabled on the relay type PLC control system. In some embodiments, the signal on the signal line 110 is generated using at least one of one-by-one communication protocol, one-by-many communication protocol, or other communication protocol.

In some embodiments, the semiconductor fabrication station controller 114 determines the station state based upon at least one of (i) a power state of the semiconductor fabrication station 150, (ii) one or more parameters of one or more components and/or one or more operations of the semiconductor fabrication station 150, or (iii) one or more measurements measured by one or more sensors disposed proximal one or more locations of the semiconductor fabrication station 150.

In some embodiments, the power state corresponds to whether the semiconductor fabrication station 150 is powered on. In some embodiments, the semiconductor fabrication station controller 114 sets the signal line 110 to the first value (e.g., normal operation) based upon a determination that the semiconductor fabrication station 150 at least one of (i) is powered on, or (ii) is receiving sufficient power from a power supply to perform one or more semiconductor fabrication processes. In some embodiments, the semiconductor fabrication station controller 114 sets the signal line 110 to the second value (e.g., abnormal operation) based upon a determination that at least one of (i) the semiconductor fabrication station 150 is powered off, or (ii) the power supply is not providing sufficient power to the semiconductor fabrication station 150 for performing one or more semiconductor fabrication processes.

In some embodiments, the semiconductor fabrication station controller 114 monitors a first parameter of the one or more parameters. In some embodiments, the semiconductor fabrication station controller 114 compares the first parameter with at least one of a first parameter threshold or a first parameter range. In some embodiments, the semiconductor fabrication station controller 114 at least one of (i) sets the signal line 110 to the first value (e.g., normal operation) based upon a determination that the first parameter exceeds the first parameter threshold or (ii) sets the signal line 110 to the second value (e.g., abnormal operation) based upon a determination that the first parameter is less than the first parameter threshold. In some embodiments, the semiconductor fabrication station controller 114 at least one of (i) sets the signal line 110 to the first value (e.g., normal operation) based upon a determination that the first parameter is less than the first parameter threshold or (ii) sets the signal line 110 to the second value (e.g., abnormal operation) based upon a determination that the first parameter exceeds the first parameter threshold.

In some embodiments, the semiconductor fabrication station controller 114 at least one of (i) sets the signal line 110 to the first value (e.g., normal operation) based upon a determination that the first parameter is inside of the first parameter range or (ii) sets the signal line 110 to the second value (e.g., abnormal operation) based upon a determination that the first parameter is outside of the first parameter range. In some embodiments, the semiconductor fabrication station controller 114 at least one of (i) sets the signal line 110 to the first value (e.g., normal operation) based upon a determination that the first parameter is outside of the first parameter range or (ii) sets the signal line 110 to the second value (e.g., abnormal operation) based upon a determination that the first parameter is inside of the first parameter range.

In some embodiments, the semiconductor fabrication station controller 114 analyzes two or more values of the first parameter to determine a first rate of change of the first parameter. In some embodiments, the first rate of change corresponds to a difference between a first value of the first parameter at a first time and a second value of the first parameter at a second time. In some embodiments, the semiconductor fabrication station controller 114 monitors the first rate of change (e.g., monitors updated values of the first rate of change). In some embodiments, the semiconductor fabrication station controller 114 compares the first rate of change with at least one of a first change threshold or a first change range. In some embodiments, the semiconductor fabrication station controller 114 at least one of (i) sets the signal line 110 to the first value (e.g., normal operation) based upon a determination that the first rate of change exceeds the first change threshold or (ii) sets the signal line 110 to the second value (e.g., abnormal operation) based upon a determination that the first rate of change is less than the first change threshold. In some embodiments, the semiconductor fabrication station controller 114 at least one of (i) sets the signal line 110 to the first value (e.g., normal operation) based upon a determination that the first rate of change is less than the first change threshold or (ii) sets the signal line 110 to the second value (e.g., abnormal operation) based upon a determination that the first rate of change exceeds the first change threshold.

In some embodiments, the semiconductor fabrication station controller 114 at least one of (i) sets the signal line 110 to the first value (e.g., normal operation) based upon a determination that the first rate of change is inside of the first change range or (ii) sets the signal line 110 to the second value (e.g., abnormal operation) based upon a determination that the first rate of change is outside of the first change range. In some embodiments, the semiconductor fabrication station controller 114 at least one of (i) sets the signal line 110 to the first value (e.g., normal operation) based upon a determination that the first rate of change is outside of the first change range or (ii) sets the signal line 110 to the second value (e.g., abnormal operation) based upon a determination that the first rate of change is inside of the first change range.

In some embodiments, at least one of (i) the first parameter corresponds to a first power level of power supplied by the power supply to the semiconductor fabrication station 150, (ii) the first parameter threshold corresponds to a threshold power level associated with the semiconductor fabrication station 150, (iii) the first parameter range corresponds to a range of power levels ranging from a minimum power level associated with the semiconductor fabrication station 150 to a maximum power level associated with the semiconductor fabrication station 150, or (iv) the first rate of change corresponds to a change in power level from the first time to the second time.

In some embodiments, the semiconductor fabrication station 150 comprises one or more sensors to determine a first measurement of the one or more measurements. In some embodiments, the one or more sensors comprise at least one of one or more proximity sensors, one or more optical sensors, one or more image sensors, one or more cameras, one or more infrared sensors, one or more pressure sensors, or one or more other suitable sensors. In some embodiments, the semiconductor fabrication station 150 uses the one or more sensors to perform measurements continuously, discontinuously, in a periodic manner, or in an aperiodic manner, to determine updated values of the first measurement. In some embodiments, the semiconductor fabrication station controller 114 monitors the first measurement (e.g., monitors the updated values of the first measurement). In some embodiments, the semiconductor fabrication station controller 114 compares the first measurement with at least one of a first measurement threshold or a first measurement range. In some embodiments, the semiconductor fabrication station controller 114 at least one of (i) sets the signal line 110 to the first value (e.g., normal operation) based upon a determination that the first measurement exceeds the first measurement threshold or (ii) sets the signal line 110 to the second value (e.g., abnormal operation) based upon a determination that the first measurement is less than the first measurement threshold. In some embodiments, the semiconductor fabrication station controller 114 at least one of (i) sets the signal line 110 to the first value (e.g., normal operation) based upon a determination that the first measurement is less than the first measurement threshold or (ii) sets the signal line 110 to the second value (e.g., abnormal operation) based upon a determination that the first measurement exceeds the first measurement threshold.

In some embodiments, the semiconductor fabrication station controller 114 at least one of (i) sets the signal line 110 to the first value (e.g., normal operation) based upon a determination that the first measurement is inside of the first measurement range or (ii) sets the signal line 110 to the second value (e.g., abnormal operation) based upon a determination that the first measurement is outside of the first measurement range. In some embodiments, the semiconductor fabrication station controller 114 at least one of (i) sets the signal line 110 to the first value (e.g., normal operation) based upon a determination that the first measurement is outside of the first measurement range or (ii) sets the signal line 110 to the second value (e.g., abnormal operation) based upon a determination that the first measurement is inside of the first measurement range.

In some embodiments, the semiconductor fabrication station controller 114 analyzes two or more values of the first measurement to determine a second rate of change of the first measurement. In some embodiments, the second rate of change corresponds to a difference between a first value of the first measurement measured using the one or more sensors at a third time and a second value of the first measurement measured using the one or more sensors at a fourth time. In some embodiments, the semiconductor fabrication station controller 114 monitors the second rate of change (e.g., monitors updated values of the second rate of change). In some embodiments, the semiconductor fabrication station controller 114 compares the second rate of change with at least one of a second change threshold or a second change range. In some embodiments, the semiconductor fabrication station controller 114 at least one of (i) sets the signal line 110 to the first value (e.g., normal operation) based upon a determination that the second rate of change exceeds the second change threshold or (ii) sets the signal line 110 to the second value (e.g., abnormal operation) based upon a determination that the second rate of change is less than the second change threshold. In some embodiments, the semiconductor fabrication station controller 114 at least one of (i) sets the signal line 110 to the first value (e.g., normal operation) based upon a determination that the second rate of change is less than the second change threshold or (ii) sets the signal line 110 to the second value (e.g., abnormal operation) based upon a determination that the second rate of change exceeds the second change threshold.

In some embodiments, the semiconductor fabrication station controller 114 at least one of (i) sets the signal line 110 to the first value (e.g., normal operation) based upon a determination that the second rate of change is inside of the second change range or (ii) sets the signal line 110 to the second value (e.g., abnormal operation) based upon a determination that the second rate of change is outside of the second change range. In some embodiments, the semiconductor fabrication station controller 114 at least one of (i) sets the signal line 110 to the first value (e.g., normal operation) based upon a determination that the second rate of change is outside of the second change range or (ii) sets the signal line 110 to the second value (e.g., abnormal operation) based upon a determination that the second rate of change is inside of the second change range.

In some embodiments, at least one of (i) the first measurement corresponds to a first pressure measurement, such as an air pressure reading taken by a sensor in an operating area of the semiconductor fabrication station 150, such as a chamber, defined by the semiconductor fabrication station 150, in which one or more operations of a semiconductor fabrication process are performed on one or more semiconductor wafers, (ii) the first measurement threshold corresponds to a threshold pressure level associated with the semiconductor fabrication station 150, (iii) the first measurement range corresponds to a range of pressure levels ranging from a minimum pressure level associated with the semiconductor fabrication station 150 to a maximum pressure level associated with the semiconductor fabrication station 150, or (iv) the second rate of change corresponds to a change in pressure level from the third time to the fourth time. In some embodiments, the semiconductor fabrication station controller 114 sets the signal line 110 to the second value (e.g., abnormal operation) in response to detecting a pressure drop or a pressure increase. In some embodiments, the pressure drop or the pressure increase is detected via a determination that the second rate of change exceeds the second change threshold.

In some embodiments, the rescue system controller 104 is configured to monitor at least one of the signal line 110 or the station state indicated by the signal line. In some embodiments, the rescue system controller 104 triggers a first set of rescue actions (e.g., a first set of one or more rescue actions) in response to the signal line 110 indicating a potential fabrication station error (e.g., in response to the signal line 110 indicating the second value) associated with the semiconductor fabrication station 150. In some embodiments, the potential fabrication station error corresponds to at least one of (i) the semiconductor fabrication station 150 being powered off, (ii) one or more components of the semiconductor fabrication station 150 malfunctioning, (iii) one or more transport vehicles not being able to access one or more areas of the semiconductor fabrication station 150 necessary to facilitate operation of the semiconductor fabrication station 150, such as for transferring semiconductor wafers between sub-stations of the semiconductor fabrication station 150, or (iv) at least one of the semiconductor fabrication station controller 114 or other component of the semiconductor fabrication station 150 failing (e.g., PLC unit failure) such that the semiconductor fabrication station 150 is unable to control and/or operate at least one of the set of drain valves 130 or the set of showerhead valves 120.

In some embodiments, the semiconductor fabrication station controller 114 sets the signal line 110 to the second value (e.g., abnormal operation) based upon a determination that at least one of (i) one or more components of the semiconductor fabrication station 150 are malfunctioning, (ii) one or more transport vehicles are not able to access the one or more areas of the semiconductor fabrication station 150 necessary to facilitate operation of the semiconductor fabrication station 150, or (iii) the semiconductor fabrication station 150 being unable to control and/or operate at least one of the set of drain valves 130 or the set of showerhead valves 120.

In some embodiments, the rescue system controller 104 monitors the signal line 110 to detect a signal change associated with the signal line 110, such as a change from the signal line 110 indicating the first value (e.g., normal operation) to the signal line 110 indicating the second value (e.g., abnormal operation). In some embodiments, the signal change associated with the signal line 110 is detected and/or flagged using a digital flag (e.g., a PLC flag) of the rescue system controller 104. In some embodiments, the signal carried by the signal line 110 corresponds to a binary signal. In some embodiments, the first value corresponds to 0 and the second value corresponds to 1. In some embodiments, the first value corresponds to 1 and the second value corresponds to 0. In some embodiments, the rescue system controller 104 triggers the first set of rescue actions in response to detecting the signal change associated with the signal line 110.

In some embodiments, the signal line 110 and/or the semiconductor fabrication station controller 114 are configured such that the signal change associated with the signal line 110 occurs when at least one of the semiconductor fabrication station 150 is powered off, the semiconductor fabrication station controller 114 fails (e.g., PLC unit failure), etc. Thus, in accordance with some embodiments, in response to at least one of the semiconductor fabrication station 150 being powered off or the semiconductor fabrication station controller 114 failing, the rescue system controller 104 detects the potential fabrication station error by detecting the signal change, and communicates with (and/or takes over control of) at least one of the set of drain valves 130 or the set of showerhead valves 120 to perform the first set of rescue actions. In some embodiments, the rescue system 102 is connected to an Uninterruptible Power Supply (UPS) that provides automated backup electric power to the rescue system 102 when an input power supply (e.g., the power supply) fails. In some embodiments, using the UPS enables the rescue system 102 to detect the signal change associated with the signal line 110 and/or perform the first set of rescue actions even in the event of a power outage.

FIG. 1B illustrates a scenario of the system 100 in which the rescue system 102 performs the first set of rescue actions, according to some embodiments. In some embodiments, the first set of rescue actions comprise at least one of (i) draining the liquid 142 (shown in FIG. 1A) from the tank 140, or (ii) emitting, through the showerhead 136, a gas 152. The gas 152 comprises at least one of nitrogen (e.g., at least one of N₂, PN2, etc.) or other suitable gas. In some embodiments, the rescue system controller 104 operates one or more drain valves of the set of drain valves 130 to drain the liquid 142 (shown in FIG. 1A) from the tank 140. In some embodiments, the rescue system controller 104 operates one or more showerhead valves of the set of showerhead valves 120 to emit the gas 152 through the showerhead 136.

In some embodiments, the rescue system controller 104 communicates with the first valve control unit 106 to control the set of drain valves 130. In some embodiments, the rescue system controller 104 communicates with the first valve control unit 106 and/or controls the set of drain valves 130 to control the state of the set of drain valves 130. In some embodiments, the rescue system controller 104 communicates with the first valve control unit 106 and/or controls the set of drain valves 130 to switch the state of the set of drain valves 130 between a second open drain state and a second closed drain state. The second open drain state is the same as or different than the first open drain state. The second closed drain state is the same as or different than the first closed drain state. In some embodiments, when the set of drain valves 130 is in the second open drain state, one or more valves of the set of drain valves 130 are opened to establish a third flow path, through the one or more valves, through which the liquid 142 is allowed to be drained from the tank 140 to the drain location 222 outside of the tank 140. The third flow path is the same as or different than the first flow path. In some embodiments, when the set of drain valves 130 is in the second closed drain state, one or more valves of the set of drain valves 130 are closed to block and/or mitigate the liquid 142 exiting the tank 140. In some embodiments, the third flow path is established using a drain component 144 of at least one of the semiconductor fabrication station 150 or the set of drain valves 130. In some embodiments, the drain component 144 comprises a valve seat (e.g., a fixed seat) of the set of drain valves 130. In some embodiments, the state of the set of drain valves 130 is controlled using at least one of the shuttle valve 132 or the valve 134.

In some embodiments, the rescue system controller 104 transmits a first communication (e.g., at least one of a message, a data packet, a value, a voltage, a wireless signal, a signal transmitted over a wired connection, etc.) to the first valve control unit 106. In some embodiments, the first communication instructs the first valve control unit 106 to set the state of the set of drain valves 130 to the second open drain state to establish the third flow path through which the liquid 142 is allowed to be drained from the tank 140 to the drain location 222 outside of the tank 140. In some embodiments, the first communication instructs the first valve control unit 106 to switch the state of the set of drain valves 130 from the second closed drain state to the second open drain state. In some embodiments, the first communication instructs the first valve control unit 106 to check the state of the set of drain valves 130 and, in response to determining that the state of the set of drain valves 130 is the second closed drain state, switch the state from the second closed drain state to the second open drain state. Although FIG. 1B shows a scenario in which the liquid 142 is completely drained from the tank 140, embodiments are contemplated in which, in response to transmitting the first communication to the first valve control unit 106, a first portion of the liquid 142 (shown in FIG. 1A) is drained from the tank 140 through the third flow path and a second portion of the liquid 142 is left in the tank 140 without being drained. Embodiments are contemplated in which all of the liquid 142 is drained from the tank 140 in response to transmitting the first communication to the first valve control unit 106.

In some embodiments, the rescue system controller 104 communicates with the second valve control unit 108 to control the set of showerhead valves 120. In some embodiments, the rescue system controller 104 communicates with the second valve control unit 108 and/or controls the set of showerhead valves 120 to control the state of the set of showerhead valves 120. In some embodiments, the rescue system controller 104 communicates with the second valve control unit 108 and/or controls the set of showerhead valves 120 to switch the state of the set of showerhead valves 120 between a second open showerhead state and a second closed showerhead state. The second open showerhead state is the same as or different than the first open showerhead state. The second closed showerhead state is the same as or different than the first closed showerhead state. In some embodiments, when the set of showerhead valves 120 is in the second open showerhead state, one or more valves of the set of showerhead valves 120 are opened to establish a fourth flow path, through the one or more valves, through which the gas 152 is allowed to flow from the gas source 226 (or a different gas source) to the showerhead 136 to be emitted through the showerhead 136. The fourth flow path is the same as or different than the second flow path. In some embodiments, when the set of showerhead valves 120 is in the second closed showerhead state, one or more valves of the set of showerhead valves 120 are closed to block and/or mitigate flow of the gas 152 to and/or through the showerhead 136.

In some embodiments, the rescue system controller 104 transmits a second communication (e.g., at least one of a message, a data packet, a value, a voltage, a wireless signal, a signal transmitted over a wired connection, etc.) to the second valve control unit 108. In some embodiments, the second communication instructs the second valve control unit 108 to set the state of the set of showerhead valves 120 to the second open showerhead state to establish the fourth flow path through which the gas 152 is allowed to flow from the gas source 226 to the showerhead 136 to be emitted through the showerhead 136. In some embodiments, the second communication instructs the second valve control unit 108 to switch the state of the set of showerhead valves 120 from the second closed showerhead state to the second open showerhead state. In some embodiments, the second communication instructs the second valve control unit 108 to check the state of the set of showerhead valves 120 and, in response to determining that the state of the set of showerhead valves 120 is the second closed showerhead state, switch the state from the second closed showerhead state to the second open showerhead state.

In some embodiments, the gas 152 is emitted at least one of towards the first semiconductor wafer 128 or into the tank 140. In some embodiments, at least some of the gas 152 impinges upon the first semiconductor wafer 128. In some embodiments, emission of the gas 152 through the showerhead 136 reduces a moisture level associated with the first semiconductor wafer 128, such as by drying the first semiconductor wafer 128. In some embodiments, the gas 152 is heated by a heater. In some embodiments, the gas 152 is not heated by a heater.

In some embodiments, the rescue system 102 comprises one or more moisture sensors (not shown) configured to measure a moisture metric corresponding to a moisture level associated with the first semiconductor wafer 128. In some embodiments, the one or more moisture sensors comprise at least one of a sensor proximal the first semiconductor wafer 128, a sensor in the tank 140, etc. In some embodiments, the rescue system 102 uses the one or more sensors to perform measurements continuously, discontinuously, in a periodic manner, or in an aperiodic manner, to determine updated values of the moisture metric. In some embodiments, the rescue system 102 monitors the moisture metric (e.g., monitors the updated values of the moisture metric). In some embodiments, the rescue system 102 compares the moisture metric with a moisture metric threshold. In some embodiments, the moisture metric being greater than the moisture metric threshold indicates that there is enough moisture (from the liquid 142, for example) to damage the first semiconductor wafer 128 if the first semiconductor wafer 128 is not dried within a threshold duration of time. In some embodiments, the moisture metric being less than the moisture metric threshold indicates that that at least one of (i) the first semiconductor wafer 128 is sufficiently dry, or (ii) there is not enough moisture (from the liquid 142, for example) to damage the first semiconductor wafer 128.

In some embodiments, in response to determining that the moisture metric is less than the moisture metric threshold, the rescue system 102 ceases emission of the gas 152 through the showerhead 136. In some embodiments, in response to determining that the moisture metric is less than the moisture metric threshold, the rescue system controller 104 transmits a third communication (e.g., at least one of a message, a data packet, a value, a voltage, a wireless signal, a signal transmitted over a wired connection, etc.) to the second valve control unit 108. In some embodiments, the third communication instructs the second valve control unit 108 to set the state of the set of showerhead valves 120 to the second closed showerhead state to block and/or mitigate flow of the gas 152 to and/or through the showerhead 136. In some embodiments, the third communication instructs the second valve control unit 108 to switch the state of the set of showerhead valves 120 from the second open showerhead state to the second closed showerhead state.

In some embodiments, the rescue system 102 performing the first set of rescue actions mitigates and/or prevents damage, such as water damage, to the first semiconductor wafer 128 that would otherwise occur if the first set of rescue actions were not performed. In some embodiments, the first semiconductor wafer 128 being in contact with and/or submerged in the liquid 142 can cause damage to the first semiconductor wafer 128. In some embodiments, the first semiconductor wafer 128 comprises a metal layer. In some embodiments, the damage includes oxidation of at least some metal of the metal layer that occurs as a result of the first semiconductor wafer 128 being in contact with and/or submerged in the liquid 142 for an extended duration of time. In some embodiments, the first semiconductor fabrication process comprises a first etching process for patterning one or more target layers of the first semiconductor wafer 128. In some embodiments, the one or more target layers of the first semiconductor wafer 128 comprise the metal layer. In some embodiments, the first etching process patterns the one or more target layers to have one or more desired shapes, such as at least one of

[symbol]

FIG. 2A illustrates a rescue scenario 200 associated with the rescue system 102 performing the first set of rescue actions, according to some embodiments. In some embodiments, the first set of rescue actions comprise conducting 202, using the set of drain valves 130 (shown in FIGS. 1A-1B), the liquid 142 from the tank 140 to the drain location 222. In some embodiments, the first set of rescue actions comprise mitigating and/or blocking 204 flow of liquid (e.g., additional liquid 142) from the liquid source 224 to the tank 140. In some embodiments, the rescue system controller 104 uses a valve control unit (not shown) to control a set of liquid source valves (e.g., a set of one or more liquid source valves) to mitigate and/or block 204 the flow of liquid from the liquid source 224 to the tank 140. In some embodiments, the first set of rescue actions comprise conducting 206, using the set of showerhead valves 120 (shown in FIGS. 1A-1B), the gas 152 from the gas source 226 to the showerhead 136 to be emitted by the showerhead 136. In some embodiments, the system 100 comprises at least one of a first rotameter 212 to measure flow of liquid between the tank 140 and the liquid source 224 or a second rotameter 214 to measure flow of gas between the showerhead 136 and the gas source 226. In some embodiments, a flow rate of liquid (e.g., de-ionized water and/or other suitable liquid) from the liquid source 224 to the tank 140 is controlled based upon a measurement determined using the first rotameter 212. In some embodiments, a flow rate of gas (e.g., nitrogen and/or other suitable gas) from the gas source 226 to the showerhead 136 is controlled based upon a measurement determined using the second rotameter 214.

In some embodiments, the rescue system 102 performing the first set of rescue actions in response to the potential fabrication station error prevents the process station from entering an overflow scenario 250 shown in FIG. 2B in accordance with some embodiments. Not performing the first set of rescue actions in response to the potential fabrication station error would increase a likelihood that the overflow scenario 250 occurs, such as due, at least in part, to at least one of (i) one or more components of the semiconductor fabrication station 150 being powered off, (ii) one or more components of the semiconductor fabrications station 150 malfunctioning, etc. Thus, in accordance with some embodiments, performing the first set of rescue actions provides for at least one of (i) protecting the first semiconductor wafer 128 from damage (e.g., water damage) by at least one of draining the liquid 142 from the tank 140 or drying the first semiconductor wafer 128 using the gas 152, or (ii) preventing the overflow scenario 250. In some embodiments, preventing the overflow scenario 250 protects one or more components of the semiconductor fabrication station 150 from damage (e.g., water damage), such as damage that would otherwise occur as a result of the liquid 142 overflowing 262 from the tank 140 in the overflow scenario 250.

In some embodiments, after performing the first set of rescue actions, one or more retrieval actions are performed to retrieve the first semiconductor wafer 128 from the tank 140. The one or more retrieval actions comprise at least one of manually retrieving the first semiconductor wafer 128 from the tank 140 or using one or more automated transport vehicles to retrieve the first semiconductor wafer 128 from the tank 140. In some embodiments, after retrieving the first semiconductor wafer 128 from the tank 140, a second semiconductor fabrication process is performed on the first semiconductor wafer 128 to produce a processed semiconductor wafer. Thus, in accordance with some embodiments, using the techniques provided herein provides for saving the first semiconductor wafer 128 from being scrapped, thereby providing for at least one of improved production efficiency and/or throughput of the semiconductor fabrication station 150, reduced waste, etc.

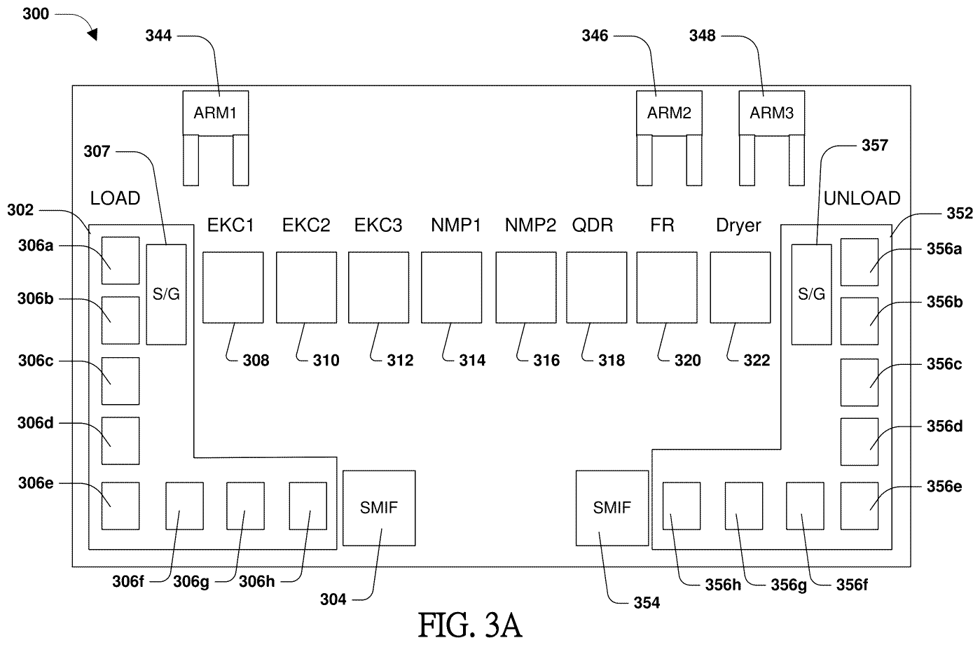

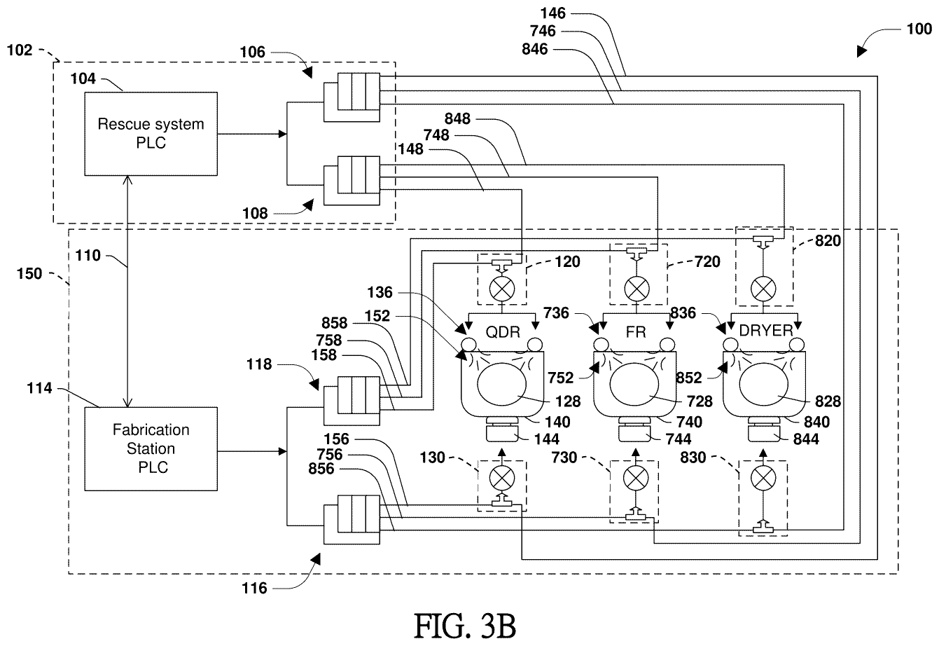

FIG. 3A illustrates a map 300 of the semiconductor fabrication station 150, in accordance with some embodiments. In some embodiments, the semiconductor fabrication station 150 comprises at least one of (i) one or more etching sub-stations for performing one or more etching acts of the first semiconductor fabrication process, such as one, some or all etching acts of a first set of etching acts, (ii) a first rinsing sub-station 318 for performing one or more first rinsing acts, (iii) a second rinsing sub-station 320 for performing one or more second rinsing acts, or (iv) a dryer sub-station 322 for performing one or more drying acts.

In some embodiments, the first set of etching acts comprises one or more wet etching acts of a wet etching process, one or more plasma etching acts of a plasma etching process, one or more dry etching acts of a dry etching process, one or more RIE acts of a RIE etching process, one or more ALE acts of a ALE etching process, one or more buffered oxide etching acts of a buffered oxide etching process, or one or more other types of etching acts.

In some embodiments, the one or more etching sub-stations of the semiconductor fabrication station 150 comprise at least one of (i) a first etching sub-station 308 “EKC1” for performing one or more first etching acts of the first set of etching acts, a second etching sub-station 310 “EKC2” for performing one or more second etching acts of the first set of etching acts, a third etching sub-station 312 “EKC3” for performing one or more third etching acts of the first set of etching acts, a fourth etching sub-station 314 “NMP1” for performing one or more fourth etching acts of the first set of etching acts, or a fifth etching sub-station 316 “NMP2” for performing one or more fifth etching acts of the first set of etching acts. In some embodiments, one or more first etching chemicals are used for at least one of the one or more first etching acts, the one or more second etching acts, or the one or more third etching acts. In some embodiments, the one or more first etching chemicals comprise one or more post-etch residue removers. In some embodiments, one or more second etching chemicals (e.g., at least one of N-Methyl-2-Pyrrolidone (NMP) etching chemicals or one more other suitable etching chemicals) are used for at least one of the one or more third etching acts or the one or more fourth etching acts. In some embodiments, the one or more second etching chemicals comprise one or more post-etch residue removers.

In some embodiments, the semiconductor fabrication station 150 comprises a loading platform 302 for loading one or more semiconductor wafers into the semiconductor fabrication station 150 and/or into one or more sub-stations of the semiconductor fabrication station 150. In some embodiments, the first semiconductor wafer 128 is transferred from a first mechanical interface 304, such as a first standard mechanical interface (SMIF), to the loading platform 302. In some embodiments, the first semiconductor wafer 128 is transferred from the first mechanical interface 304 to the loading platform 302 using a mechanical transfer component, such as at least one of a robotic arm or other suitable component.

In some embodiments, the first mechanical interface 304 comprises a first wafer storage device. In some embodiments, the first wafer storage device comprises at least one of a front opening unified pod (FOUP), a cassette pod, a reticle pod, or other type of wafer storage device. In some embodiments, the first wafer storage device is used to store one or more semiconductor wafers comprising the first semiconductor wafer 128. In some embodiments, the one or more semiconductor wafers comprise a batch of wafers. In some embodiments, the one or more semiconductor wafers comprise at least one of one or more substrates, one or more photomasks, one or more semiconductor devices, one or more dies, etc. In some embodiments, the one or more semiconductor wafers are stacked vertically in the first wafer storage device. In some embodiments, the one or more semiconductor wafers are supported by a support frame, of the first wafer storage device, having at least one of wafer shelves or wafer slots.

In some embodiments, the first semiconductor wafer 128 is transported in a first cassette, such as a cassette of a first set of cassettes 306a-306h, along the loading platform 302 to a first mechanical transfer component 307, such as a first space change (S/G) component. In some embodiments, the first mechanical transfer component 307 is used to at least one of separate the first semiconductor wafer 128 from the first cassette or transfer the first semiconductor wafer 128 from the first cassette to a sub-station of the semiconductor fabrication station 150. In some embodiments, the semiconductor fabrication station 150 comprises one or more transport vehicles comprising at least one of a first transport vehicle 344, a second transport vehicle 346, or a third transport vehicle 348. In some embodiments, a transport vehicle of the one or more transport vehicles is used to transport the first semiconductor wafer 128 from one sub-station of the semiconductor fabrication station 150 to another sub-station of the semiconductor fabrication station 150. In some embodiments, a transport vehicle of the one or more transport vehicles comprises at least one of a robot, an overhead transport vehicle, a guided transport vehicle that travels on predetermined routes or tracks, etc.

In some embodiments, the first etching process comprises at least one of (i) a first etching stage in which the first semiconductor wafer 128 undergoes the one or more first etching acts performed using the first etching sub-station 308, (ii) a second etching stage in which the first semiconductor wafer 128 undergoes the one or more second etching acts performed using the second etching sub-station 310, (iii) a third etching stage in which the first semiconductor wafer 128 undergoes the one or more third etching acts performed using the third etching sub-station 312, (iv) a fourth etching stage in which the first semiconductor wafer 128 undergoes the one or more fourth etching acts performed using the fourth etching sub-station 314, (v) a fifth etching stage in which the first semiconductor wafer 128 undergoes the one or more fifth etching acts performed using the fifth etching sub-station 316, (vi) a first rinsing stage in which the first semiconductor wafer 128 undergoes the one or more first rinsing acts performed using the first rinsing sub-station 318, (vii) a second rinsing stage in which the first semiconductor wafer 128 undergoes the one or more FR acts performed using the second rinsing sub-station 320, (viii) a dry stage in which the first semiconductor wafer 128 undergoes the one or more drying acts performed using the dryer sub-station 322, (ix) or one or more other semiconductor fabrication stages. In some embodiments, a transport vehicle of the one or more transport vehicles is configured to at least one of transport the first semiconductor wafer 128 from the first etching sub-station 308 to the second etching sub-station 310 in response to the first etching stage, transport the first semiconductor wafer 128 from the second etching sub-station 310 to the third etching sub-station 312 in response to the second etching stage, transport the first semiconductor wafer 128 from the third etching sub-station 312 to the fourth etching sub-station 314 in response to the third etching stage, transport the first semiconductor wafer 128 from the fourth etching sub-station 314 to the fifth etching sub-station 316 in response to the fourth etching stage, transport the first semiconductor wafer 128 from the fifth etching sub-station 316 to the first rinsing sub-station 318 in response to the fifth etching stage, transport the first semiconductor wafer 128 from the first rinsing sub-station 318 to the second rinsing sub-station 320 in response to the first rinsing stage, or transport the first semiconductor wafer 128 from the second rinsing sub-station 320 to the dryer sub-station 322 in response to the second rinsing stage. Other arrangements of sub-stations of the semiconductor fabrication station 150 and orders of stages of the first semiconductor fabrication process other than those shown in and/or described with respect to FIG. 3A are within the scope of the present disclosure.

In some embodiments, the one or more first rinsing acts of the first rinsing stage comprise one or more Quick Dump Rinse (QDR) acts of a QDR stage (e.g., water bath). In some embodiments, the one or more QDR acts comprise submerging at least a portion of the first semiconductor wafer 128 in a liquid in the first rinsing sub-station 318 (e.g., a QDR sub-station) for a first period of time. Other types of rinsing acts of the first rinsing stage are within the scope of the present disclosure. In some embodiments, performing the one or more first rinsing acts (e.g., the one or more QDR acts) removes contaminants from the first semiconductor wafer 128. In some embodiments, performing the one or more first rinsing acts (e.g., the one or more QDR acts) removes, from the first semiconductor wafer 128, residue from one or more prior stages of the first semiconductor fabrication process, such as at least one of the first etching stage, the second etching stage, the third etching stage, the fourth etching stage, or the fifth etching stage. In some embodiments, the residue comprises at least one of etchants, metal residue etched from the first semiconductor wafer 128, or other particles.

In some embodiments, the one or more second rinsing acts of the second rinsing stage comprise one or more Final Rinse (FR) acts of an FR stage. In some embodiments, the one or more FR acts comprise submerging at least a portion of the first semiconductor wafer 128 in a liquid in the second rinsing sub-station 320 (e.g., a FR sub-station) for a second period of time. In some embodiments, a water resistivity meter is used to monitor a resistivity and/or purity of the liquid in the second rinsing sub-station 320. In some embodiments, a purity of the liquid is increased in response to determining that a resistance measurement determined using the water resistivity meter is greater than a threshold resistance. In some embodiments, a duration of the second period of time is greater than a duration of the first period of time. Other types of rinsing acts of the second rinsing stage are within the scope of the present disclosure. In some embodiments, performing the one or more second rinsing acts (e.g., the one or more FR acts) removes contaminants from the first semiconductor wafer 128. In some embodiments, performing the one or more second rinsing acts (e.g., the one or more FR acts) removes, from the first semiconductor wafer 128, residue from one or more prior stages of the first semiconductor fabrication process, such as at least one of the first etching stage, the second etching stage, the third etching stage, the fourth etching stage, or the fifth etching stage. In some embodiments, the residue comprises at least one of etchants, metal residue etched from the first semiconductor wafer 128, or other particles.

In some embodiments, the one or more drying acts of the dry stage are performed using the dryer sub-station 322. In some embodiments, the one or more drying acts comprise one or more acts of Marangoni drying process or other suitable drying process. In some embodiments, performing the one or more drying acts dries the first semiconductor wafer 128.

In some embodiments, the semiconductor fabrication station 150 comprises an unloading platform 352 for transferring one or more semiconductor wafers from the semiconductor fabrication station 150 to a second mechanical interface 354, such as a second SMIF. In some embodiments, a second mechanical transfer component 357, such as a second S/G component, is used to transfer the first semiconductor wafer 128 from a sub-station (e.g., the dryer sub-station 322) of the semiconductor fabrication station 150 to the unloading platform 352. In some embodiments, the second mechanical interface 354 comprises a second wafer storage device. In some embodiments, the first semiconductor wafer 128 is transported in a second cassette, such as a cassette of a second set of cassettes 356a-356h, along the unloading platform 352 to the second mechanical interface 354. In some embodiments, the first semiconductor wafer 128 is transferred from the unloading platform 352 to the second mechanical interface 354 using a mechanical transfer component, such as at least one of a robotic arm or other suitable component.

FIG. 3B illustrates the system 100, according to some embodiments. In some embodiments, in response to the signal change associated with the signal line 110, the rescue system 102 performs rescue actions for at least one of the first rinsing sub-station 318, the second rinsing sub-station 320, or the dryer sub-station 322. In some embodiments, the first rinsing sub-station 318 (e.g., the QDR sub-station) comprises at least one of the tank 140, the showerhead 136, the set of showerhead valves 120, the set of drain valves 130, or the drain component 144.

In some embodiments, the second rinsing sub-station 320 (e.g., the FR sub-station) comprises at least one of a second tank 740, a second showerhead 736, a second set of showerhead valves 720, a second set of drain valves 730, or a second drain component 744. In some embodiments, at least one of the second tank 740, the second showerhead 736, the second set of showerhead valves 720, the second set of drain valves 730, or the second drain component 744 each comprises one or more of the features, components, interrelationships with other components, uses, etc., provided herein with respect to at least one of the tank 140, the showerhead 136, the set of showerhead valves 120, the set of drain valves 130, or the drain component 144, respectively.

In some embodiments, the dryer sub-station 322 comprises at least one of a third tank 840, a third showerhead 836, a third set of showerhead valves 820, a third set of drain valves 830, or a third drain component 844. In some embodiments, at least one of the third tank 840, the third showerhead 836, the third set of showerhead valves 820, the third set of drain valves 830, or the third drain component 844 each comprises one or more of the features, components, interrelationships with other components, uses, etc., provided herein with respect to at least one of the tank 140, the showerhead 136, the set of showerhead valves 120, the set of drain valves 130, or the drain component 144, respectively.

In some embodiments, the first valve control unit 106 is configured to control at least one of the second set of drain valves 730 or the third set of drain valves 830. In some embodiments, the second valve control unit 108 is configured to control at least one of the second set of showerhead valves 720 or the third set of showerhead valves 820. In some embodiments, the first valve control unit 106 at least one of (i) is connected to (and/or controls) the second set of drain valves 730 via a fifth set of tubes 746 configured to conduct fluid comprising at least one of liquid or gas between the first valve control unit 106 and the second set of drain valves 730 or (ii) is connected to (and/or controls) the third set of drain valves 830 via a sixth set of tubes 846 configured to conduct fluid comprising at least one of liquid or gas between the first valve control unit 106 and the third set of drain valves 830. In some embodiments, the second valve control unit 108 at least one of (i) is connected to (and/or controls) the second set of showerhead valves 720 via a seventh set of tubes 748 configured to conduct fluid comprising at least one of liquid or gas between the second valve control unit 108 and the second set of showerhead valves 720 or (ii) is connected to (and/or controls) the third set of showerhead valves 820 via an eighth set of tubes 848 configured to conduct fluid comprising at least one of liquid or gas between the second valve control unit 108 and the third set of showerhead valves 820.

In some embodiments, the third valve control unit 116 is configured to control at least one of the second set of drain valves 730 or the third set of drain valves 830. In some embodiments, the fourth valve control unit 118 is configured to control at least one of the second set of showerhead valves 720 or the third set of showerhead valves 820. In some embodiments, the third valve control unit 116 at least one of (i) is connected to (and/or controls) the second set of drain valves 730 via a ninth set of tubes 756 configured to conduct fluid comprising at least one of liquid or gas between the third valve control unit 116 and the second set of drain valves 730 or (ii) is connected to (and/or controls) the third set of drain valves 830 via a tenth set of tubes 856 configured to conduct fluid comprising at least one of liquid or gas between the third valve control unit 116 and the third set of drain valves 830. In some embodiments, the fourth valve control unit 118 at least one of (i) is connected to (and/or controls) the second set of showerhead valves 720 via an eleventh set of tubes 758 configured to conduct fluid comprising at least one of liquid or gas between the fourth valve control unit 118 and the second set of showerhead valves 720 or (ii) is connected to (and/or controls) the third set of showerhead valves 820 via a twelfth set of tubes 858 configured to conduct fluid comprising at least one of liquid or gas between the fourth valve control unit 118 and the third set of showerhead valves 820.

In some embodiments, in response to at least one of the signal line 110 indicating the potential fabrication station error or the signal change associated with the signal line 110, the rescue system 102 performs at least one of (i) the first set of rescue actions to at least one of drain the liquid 142 (shown in FIG. 1A) from the tank 140 or emit the gas 152 through the showerhead 136 (while the first semiconductor wafer 128 is undergoing a bath, such as a de-ionized water bath, of the first rinsing stage in the tank 140, for example), (ii) a second set of rescue actions to at least one of drain a second liquid (e.g., at least one of water, de-ionized water, one or more cleaning chemicals, one or more etching chemicals, or one or more other suitable substances) from the second tank 740 or emit a second gas 752 (e.g., at least one of nitrogen or other suitable gas) through the second showerhead 736 to reduce a moisture level associated with a second semiconductor wafer 728 disposed in the second tank 740 (while the second semiconductor wafer 728 is undergoing a bath, such as a de-ionized water bath, of the second rinsing stage in the second tank 740, for example), or (iii) a third set of rescue actions to at least one of drain a third liquid (e.g., at least one of water, de-ionized water, one or more cleaning chemicals, one or more etching chemicals, or one or more other suitable substances) from the third tank 840 or emit a third gas 852 (e.g., at least one of nitrogen or other suitable gas) through the third showerhead 836 to reduce a moisture level associated with a third semiconductor wafer 828 disposed in the third tank 840 (while the third semiconductor wafer 828 is undergoing a bath, such as a de-ionized water bath, of the third rinsing stage in the third tank 840, for example).

In some embodiments, the second set of rescue actions comprises one, some or all of the actions provided herein with respect to the first set of rescue actions. In some embodiments, the second set of rescue actions is performed using one, some, or all of the techniques provided herein with respect to the first set of rescue actions. In some embodiments, the third set of rescue actions comprises one, some or all of the actions provided herein with respect to the first set of rescue actions. In some embodiments, the third set of rescue actions is performed using one, some, or all of the techniques provided herein with respect to the first set of rescue actions. In some embodiments, at least two of the first set of rescue actions, the second set of rescue actions, or the third set of rescue actions are performed by the rescue system 102 concurrently and/or simultaneously.

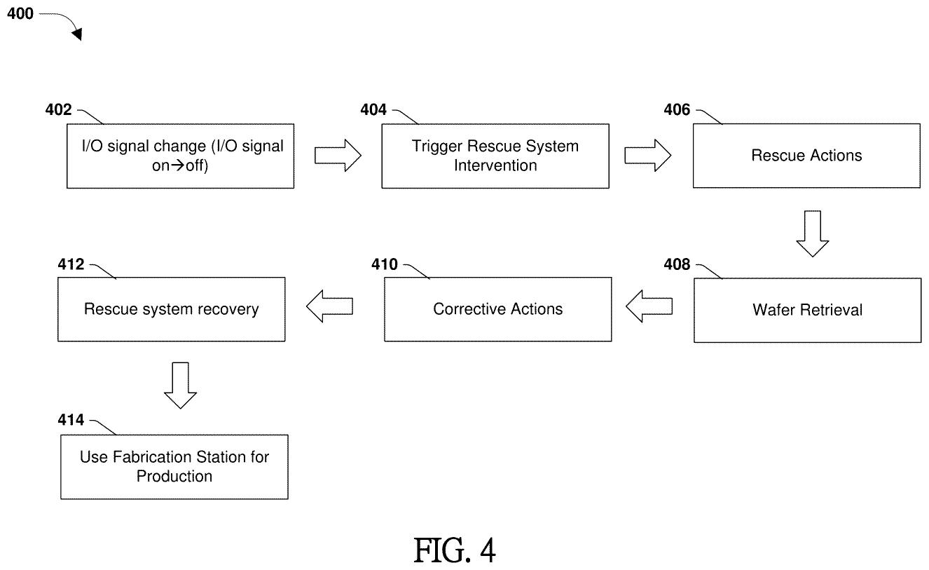

FIG. 4 illustrates a method 400 of operating the rescue system 102 and the semiconductor fabrication station 150, in accordance with some embodiments. At 402, the signal line 110 undergoes the signal change (e.g., at least one of 1 to 0, on to off, etc.) associated with the potential fabrication station error. At 404, the rescue system controller 104 triggers a rescue system intervention in response to the signal change associated with the signal line 110. At 406, the rescue system 102 performs the first set of rescue actions. In some embodiments, the rescue system 102 performs the first set of rescue actions immediately upon (and/or within about 10 seconds of) the signal change and/or triggering the rescue system intervention. At 408, the one or more retrieval actions are performed to retrieve the first semiconductor wafer 128 from the tank 140. In some embodiments, the one or more retrieval actions are performed when at least a threshold amount of the liquid 142 (shown in FIG. 1A) is drained from the tank 140 or the liquid 142 is entirely drained from the tank 140.

At 410, the rescue system 102 performs one or more corrective actions. In some embodiments, the one or more corrective actions comprise at least one of (i) displaying, on a display panel, an alert indicative of at least one of the potential fabrication station error or the semiconductor fabrication station 150, (ii) transmitting a signal to one or more devices, such as at least one of a phone, a smartphone, a mobile phone, a landline, a laptop, a desktop computer, hardware, or other type of device, wherein the signal is indicative of at least one of the potential fabrication station error or the semiconductor fabrication station 150, (iii) allocating one or more resources to the semiconductor fabrication station 150 to address the potential fabrication station error, wherein the one or more resources comprise at least one of manpower (e.g., a technician and/or engineer), tools, replacement parts, etc., or (iv) using the one or more resources to perform one or more maintenance operations comprising at least one of diagnosing, repairing, replacing, resetting, reconfiguring, etc. one or more components of the semiconductor fabrication station 150. In some embodiments, while the one or more maintenance operations, at least one of the semiconductor fabrication station 150 is in a first debugging state or the rescue system 102 is in a second debugging state.

At 412, a rescue system recovery is performed. In some embodiments, the rescue system recovery comprises at least one of (i) switching the semiconductor fabrication station 150 from the first debugging state to a first automated state, or (ii) switching the rescue system 102 from the second debugging state to a second automated state. At 414, the semiconductor fabrication station 150 is used for processing one or more semiconductor wafers, such as using one or more of the techniques provided herein with respect to performing the first semiconductor fabrication process on the first semiconductor wafer 128.

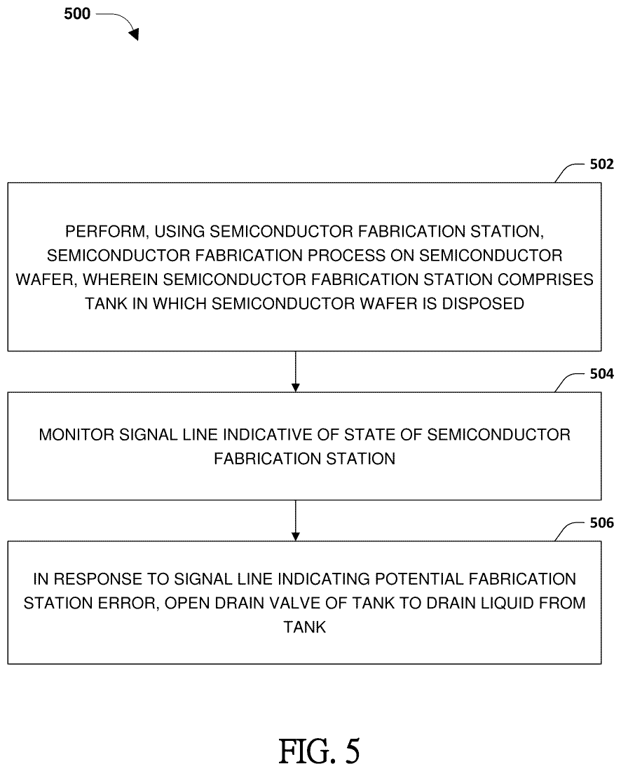

A method 500 is illustrated in FIG. 5 in accordance with some embodiments. The method 500 includes performing, at 502, a semiconductor fabrication process (e.g., the first semiconductor fabrication process) on a semiconductor wafer (e.g., the first semiconductor wafer 128) using a semiconductor fabrication station (e.g., the semiconductor fabrication station 150). In some embodiments, the semiconductor fabrication station includes a tank (e.g., the tank 140) in which the semiconductor wafer is disposed. The method 500 includes monitoring, at 504, a signal line (e.g., the signal line 110) indicative of a state of the semiconductor fabrication station. The method 500 includes opening, at 506, a drain valve (e.g., at least one of the shuttle valve 132, the valve 134, or other valve of the set of drain valves 130) of the tank to drain a liquid (e.g., the liquid 142) from the tank in response to the signal line indicating a potential fabrication station error.

In some embodiments, the semiconductor fabrication station comprises a showerhead (e.g., the showerhead 136). In some embodiments, the method 500 includes opening a showerhead valve (e.g., at least one of the shuttle valve 122, the valve 124, or other valve of the set of showerhead valves 120) to emit a gas (e.g., the gas 152) through the showerhead.

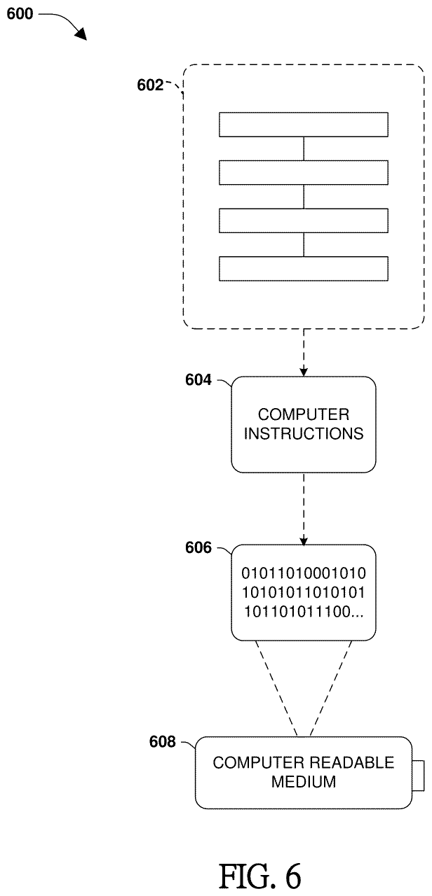

One or more embodiments involve a computer-readable medium comprising processor-executable instructions configured to implement one or more of the techniques presented herein. An exemplary computer-readable medium is illustrated in FIG. 6, wherein the embodiment 600 comprises a computer-readable medium 608 (e.g., a CD-R, DVD-R, flash drive, a platter of a hard disk drive, etc.), on which is encoded computer-readable data 606. This computer-readable data 606 in turn comprises a set of processor-executable computer instructions 604 configured to implement one or more of the principles set forth herein when executed by a processor. In some embodiments 600, the processor-executable computer instructions 604 are configured to implement a method 602, such as at least some of the aforementioned method(s) when executed by a processor. In some embodiments, the processor-executable computer instructions 604 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a system is provided. The system includes a semiconductor fabrication station and a rescue system. The semiconductor fabrication station includes a tank to hold a liquid. The semiconductor fabrication station is configured to perform a semiconductor fabrication process on a semiconductor wafer disposed in the tank. The rescue system is configured to monitor a signal line indicative of a state of the semiconductor fabrication station. The rescue system is configured to open a drain valve of the tank to drain the liquid from the tank in response to the signal line indicating a potential fabrication station error.

In some embodiments, a method is provided. The method includes performing, using a semiconductor fabrication station, a semiconductor fabrication process on a semiconductor wafer, wherein the semiconductor fabrication station includes a tank in which the semiconductor wafer is disposed. The method includes monitoring a signal line indicative of a state of the semiconductor fabrication station. The method includes opening a drain valve of the tank to drain a liquid from the tank in response to the signal line indicating a potential fabrication station error.

In some embodiments, a system is provided. The system includes a semiconductor fabrication station and a rescue system. The semiconductor fabrication station includes a tank to hold a liquid and a showerhead. The rescue system is configured to monitor a signal line indicative of a state of the semiconductor fabrication station. In response to the signal line indicating a potential fabrication station error, the rescue system is configured to at least one of open a drain valve of the tank to drain the liquid from the tank or emit a gas through the showerhead.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A system, comprising:
a semiconductor fabrication station comprising a tank to hold a liquid, wherein the semiconductor fabrication station is configured to perform a semiconductor fabrication process on a semiconductor wafer disposed in the tank; and
a rescue system configured to:
monitor a signal line indicative of a state of the semiconductor fabrication station; and
in response to the signal line indicating a potential fabrication station error, open a drain valve of the tank to drain the liquid from the tank.

2. The system of claim 1, wherein the rescue system comprises:
a valve control unit configured to control the drain valve; and
a programmable logic controller (PLC) connected to the signal line and configured to instruct the valve control unit to open the drain valve in response to the signal line indicating the potential fabrication station error.

3. The system of claim 1, wherein:
the semiconductor fabrication station comprises a showerhead; and
in response to the signal line indicating the potential fabrication station error, the rescue system is configured to emit, through the showerhead, a gas.

4. The system of claim 3, wherein:
the gas comprises nitrogen.

5. The system of claim 3, wherein:
emission of the gas through the showerhead reduces a moisture level associated with the semiconductor wafer.

6. The system of claim 3, wherein the rescue system comprises:
a first valve control unit configured to control the drain valve;
a second valve control unit configured to control a showerhead valve connected to the showerhead; and
a programmable logic controller (PLC) connected to the signal line, wherein in response to the signal line indicating the potential fabrication station error, the PLC is configured to:
instruct the first valve control unit to open the drain valve; and
instruct the second valve control unit to open the showerhead valve to emit the gas through the showerhead.

7. The system of claim 6, wherein at least one of:
the drain valve comprises a first shuttle valve; or
the showerhead valve comprises a second shuttle valve.

8. The system of claim 1, wherein:
the liquid comprises de-ionized water.

9. The system of claim 1, wherein:
the semiconductor fabrication process comprises an etching process.

10. The system of claim 1, wherein:
the semiconductor wafer is disposed in the tank during a Quick Dump Rinse (QDR) stage of the semiconductor fabrication process.

11. The system of claim 1, wherein:
the semiconductor wafer is disposed in the tank during a Final Rinse (FR) stage of the semiconductor fabrication process.

12. The system of claim 1, wherein:
the semiconductor wafer is disposed in the tank during a dry stage of the semiconductor fabrication process.

13. A method comprising:
performing, using a semiconductor fabrication station, a semiconductor fabrication process on a semiconductor wafer, wherein the semiconductor fabrication station comprises a tank in which the semiconductor wafer is disposed;
monitoring a signal line indicative of a state of the semiconductor fabrication station; and
in response to the signal line indicating a potential fabrication station error, opening a drain valve of the tank to drain a liquid from the tank.

14. The method of claim 13, comprising:
in response to the signal line indicating the potential fabrication station error, emitting a gas through a showerhead of the semiconductor fabrication station to reduce a moisture level associated with the semiconductor wafer.

15. The method of claim 13, comprising:
after opening the drain valve of the tank to drain the liquid from the tank, retrieving the semiconductor wafer from the tank.

16. The method of claim 15, comprising:
after retrieving the semiconductor wafer from the tank, performing a second semiconductor fabrication process on the semiconductor wafer to produce a processed semiconductor wafer.

17. A system, comprising:
a semiconductor fabrication station comprising a tank to hold a liquid and a showerhead; and
a rescue system configured to:
monitor a signal line indicative of a state of the semiconductor fabrication station; and
in response to the signal line indicating a potential fabrication station error, at least one of:
open a drain valve of the tank to drain the liquid from the tank; or
emit, through the showerhead, a gas.

18. The system of claim 17, wherein at least one of:
the gas comprises nitrogen; or
the liquid comprises de-ionized water.

19. The system of claim 17, wherein:
emission of the gas through the showerhead reduces a moisture level associated with a semiconductor wafer disposed in the tank.

20. The system of claim 17, wherein the rescue system comprises:
a first valve control unit configured to control the drain valve;
a second valve control unit configured to control a showerhead valve connected to the showerhead; and
a programmable logic controller (PLC) connected to the signal line, wherein in response to the signal line indicating the potential fabrication station error, the PLC is configured to:
instruct the first valve control unit to open the drain valve; and
instruct the second valve control unit to open the showerhead valve to emit the gas through the showerhead.
